(19) United States
(12) Patent Application Publication
(10) Pub. No.: US 2013/0157385 A1
(43) Pub. Date: Jun. 20, 2013

(54) METHOD FOR FABRICATING SEMICONDUCTOR DEVICE

(71) Applicants: Bo Kyoung JUNG, Icheon-si (KR); Min Suk Lee, Seongnam-si (KR)

(72) Inventors: Bo Kyoung JUNG, Icheon-si (KR); Min Suk Lee, Seongnam-si (KR)

(21) Appl. No.: 13/529,306

(22) Filed: Jun. 21, 2012

(30) Foreign Application Priority Data
Dec. 16, 2011 (KR) 10-2011-0136652

(51) Int. Cl. H01L 43/12

(52) U.S. Cl. 438/3; 257/E43.006

(57) ABSTRACT

A method for fabricating a semiconductor device includes forming a bottom-electrode metal layer over a substrate, planarizing the bottom-electrode metal layer by a first thickness through a chemical mechanical polishing (CMP) process, etching the bottom-electrode metal layer by a second thickness through a wet etching process, forming a plurality of layers of a magnetic tunneling junction (MTJ) element over the bottom-electrode metal layer, forming a top electrode over the plurality of layers, and forming the MTJ element and a bottom electrode by etching the plurality of layers and the bottom-electrode metal layer using the top electrode as an etch mask.

### CROSS-REFERENCE TO RELATED APPLICATIONS

The present application claims priority of Korean Patent Application No. 10-2011-0136652, filed on Dec. 16, 2011, which is incorporated herein by reference in its entirety.

### BACKGROUND

1. Field

Exemplary embodiments of the present invention relate to a method for fabricating a semiconductor device, and more particularly, to a method for fabricating a semiconductor device having a magnetoresistive element.

2. Description of the Related Art

DRAM is a representative semiconductor memory device, which is widely used, and has features of a high-speed operation and high integration. However, DRAM as a volatile memory loses data stored therein when power supply is cut off and continuously rewrite data through a refresh operation. Therefore, DRAM may consume power significantly. Meanwhile, a flash memory exhibits non-volatility and high-integration characteristics but has features of a low operation speed. Furthermore, a magnetoresistive memory which stores information using a magnetic resistance difference exhibits a nonvolatile characteristic and performs a high-speed operation while enabling high integration.

The magnetoresistive memory is referred to as a nonvolatile memory device which stores data using magnetic resistance changing based on a magnetization direction between ferromagnetic substances. A magnetoresistive element has low resistance, when the spin directions of two magnetic layers, i.e., the directions of magnetic momentums are equal to each other, and has high resistance when the spin directions are opposite to each other. The magnetic resistance memory stores data, based on the fact that the resistance of the magnetic resistance element, i.e., a memory cell, differs depending on the magnetization states of the magnetic layers. A magnetic tunneling junction (MTJ) element has been widely used as the magnetoresistive element.

In general, the magnetoresistive memory with an MTJ element has a structure of a ferromagnetic layer, an insulation layer, and a ferromagnetic layer. When an electron passes through the insulation layer used as a tunneling barrier from the first ferromagnetic layer, a tunneling probability differs depending on the magnetization direction of the second ferromagnetic layer. That is, the degree of tunneling the insulation layer by the electron differs. When the magnetization directions of the two ferromagnetic layers are parallel, a tunneling current is maximized, and when the magnetization directions are antiparallel, the tunneling current is minimized. For example, it may be considered that, when a resistance value decided by the tunneling current is large, data ‘1’ (or ‘0’) is written, and when the resistance value is small, data ‘0’ (or ‘1’) is written. Here, one of the two ferromagnetic layers is generally referred to as a fixed magnetization layer of which the magnetization direction is fixed, and the other is referred to as a free magnetization layer of which the magnetization direction is reversed by an external magnetic field or current.

When the MTJ element is fabricated, there are difficulties in patterning the ferromagnetic layer, the insulation layer, and the ferromagnetic layer, which form the MTJ element. Furthermore, since the MTJ element is very sensitive to stress, a protective layer is to be formed to prevent the MTJ element from being damaged even after the patterning process.

### SUMMARY

An embodiment of the present invention is directed to a method for fabricating a semiconductor device having a magnetoresistive element, which is capable of increasing the reliability of a patterning process for forming an MTJ element.

In accordance with an embodiment of the present invention, a method for fabricating a semiconductor device includes: forming a bottom-electrode metal layer over a substrate; planarizing the bottom-electrode metal layer by a first thickness through a chemical mechanical polishing (CMP) process; etching the bottom-electrode metal layer by a second thickness through a wet etching process; forming a plurality of layers of an MTJ element over the bottom-electrode metal layer; forming a top electrode over the plurality of layers; and forming the MTJ element and a bottom electrode by etching the plurality of layers and the bottom-electrode metal layer using the top electrode as an etch mask.

In accordance with another embodiment of the present invention, a method for fabricating a semiconductor device includes: forming a bottom-electrode metal layer over a substrate; planarizing the bottom-electrode metal layer by a first thickness through a chemical mechanical polishing (CMP) process; etching the bottom-electrode metal layer by a second thickness through a dry etching process; forming a plurality of layers of a magnetic tunneling junction (MTJ) element over the bottom-electrode metal layer; forming a top electrode over the plurality of layers; and forming the MTJ element and a bottom electrode by etching the plurality of layers and the bottom-electrode metal layer using the top electrode an etch mask.

In accordance with further embodiment of the present invention, a method for fabricating a semiconductor device includes: forming a metal layer of a bottom electrode over a substrate; performing a first etching process to form the metal layer of a first thickness; performing a second etching process to form the metal layer of a second thickness; forming a plurality of layers of a magnetic tunneling junction (MTJ) element over the metal layer; forming a top electrode over the plurality of layers; and forming the MTJ element and a bottom electrode by etching the plurality of layers and the metal layer using the top electrode as an etch mask.

### BRIEF DESCRIPTION OF THE DRAWINGS

FIGS. 1A to 1D are cross-sectional views illustrating a method for fabricating a semiconductor device in accordance with an embodiment of the present invention.

FIGS. 2A to 2D are cross-sectional views illustrating a method for fabricating a semiconductor device in accordance with a first embodiment of the present invention.

FIGS. 3A to 3D are cross-sectional views illustrating a method for fabricating a semiconductor device in accordance with a second embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

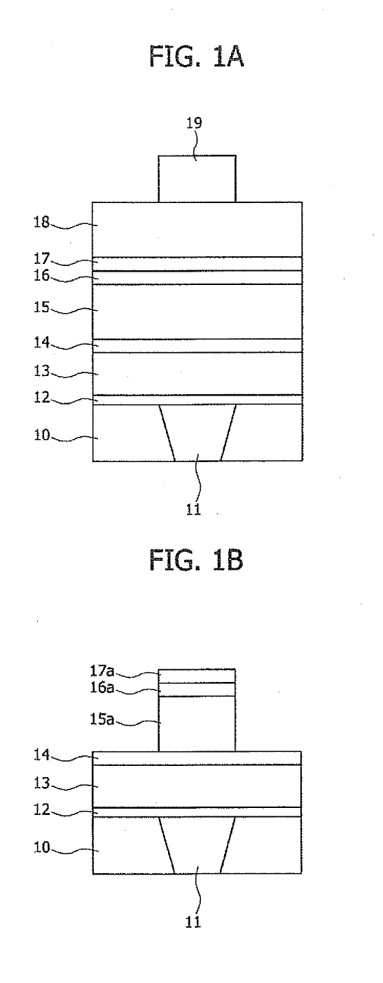

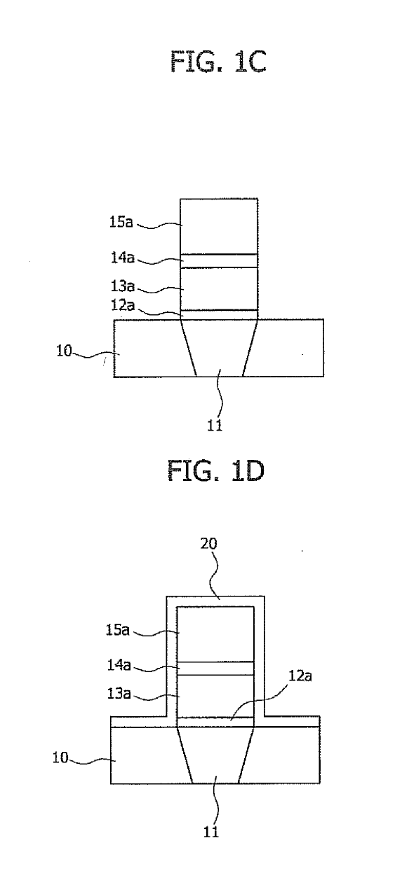

FIGS. 1A to 1D are cross-sectional views illustrating a method for fabricating a semiconductor device in accordance with an embodiment of the present invention.

Referring to FIG. 1A, a bottom-electrode metal layer 12 is formed over a bottom layer 10 having a contact plug 11 formed therein. The bottom-electrode metal layer 12 may be formed of titanium nitride. The bottom-electrode metal layer 12 is planarized by a chemical mechanical polishing (CMP) process.

A plurality of layers 13 for constructing an MTJ element are formed over the bottom-electrode metal layer 12. The plurality of layers 13 for constructing an MTJ element may include a ferromagnetic layer, a tunnel insulation layer, and a ferromagnetic layer.

First to third top-electrode metal layers 14 to 16 are formed over the plurality of layers 13 for constructing an MTJ element. The first to third top-electrode metal layers 14 to 16 may be formed of a ruthenium layer, a tungsten layer, and a tantalum layer, respectively.

An insulation layer 17 is formed over the first to third top-electrode metal layers 14 to 16, and a carbon layer 18 is formed over the insulation layer 17. A photoresist pattern 19 is formed over the carbon layer 18.

Referring to FIG. 1B, the carbon layer 18 is patterned by using the photoresist pattern 19 as an etch mask. Using the patterned carbon layer 18 as an etch mask, the second and third top-electrode metal layers 15 and 16 are patterned to form top electrodes 15a and 16a. During this process, the insulation layer 17 is patterned.

Referring to FIG. 1C, the top electrodes 15a and 16b are used to pattern the first top-electrode metal layer 14, the plurality of layers 13 for constructing an MTJ element, and the bottom-electrode metal layer 12, thereby forming a top electrode 14a, an MTJ element 13a, and a bottom electrode 12a.

Referring to FIG. 1D, a capping layer 20 is formed to cover the bottom electrode 12a, the MTJ element 13a, and the top electrodes 14a, 15a, and 16a. The capping layer 20 may be formed of silicon nitride. The capping layer 20 serves to prevent the MTJ element 13a from being damaged during a subsequent process for forming a contact plug which is to be coupled to the top electrodes 14a, 15a, and 16a through an insulation layer (not illustrated) to be formed over the top electrodes 14a, 15a, and 16a.

During the patterning process for the MTJ element and the patterning process for the bottom electrode in the above-described method for fabricating a semiconductor device having the MTJ element, the top electrodes 15a and 16a serve as an etch mask. Therefore, the thicknesses of the top electrodes 15a and 16a are decided in consideration of patterning the bottom electrode and the MTJ.

When the thickness of titanium nitride used as the bottom electrode is large, for example, equal to or more than 50 Å, the thickness of the top electrodes is to be large enough to perform the bottom electrode patterning. Furthermore, a time taken to pattern the MTJ element may excessively increase. However, it is not easy to uniformly form the bottom-electrode metal layer 12 to have a thickness of 50 Å or less only through a CMP process. Furthermore, when the thickness of the top electrodes is excessively increased, the thickness of the carbon layer for patterning the top electrodes may be excessively increased as well.

Therefore, the present invention provides a method for fabricating a semiconductor device, in which a process of patterning an MTJ element is performed after a process of adequately reducing the thickness of a metal layer used as a bottom electrode.

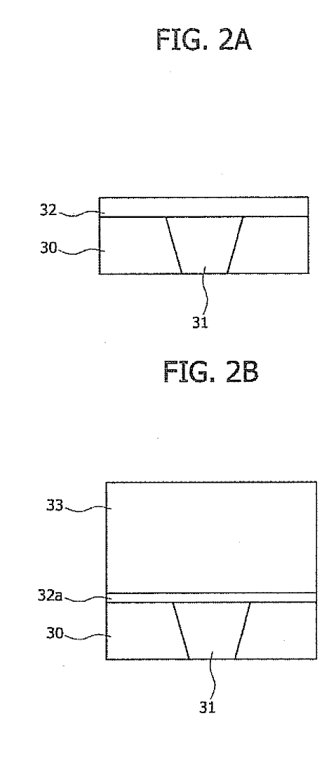

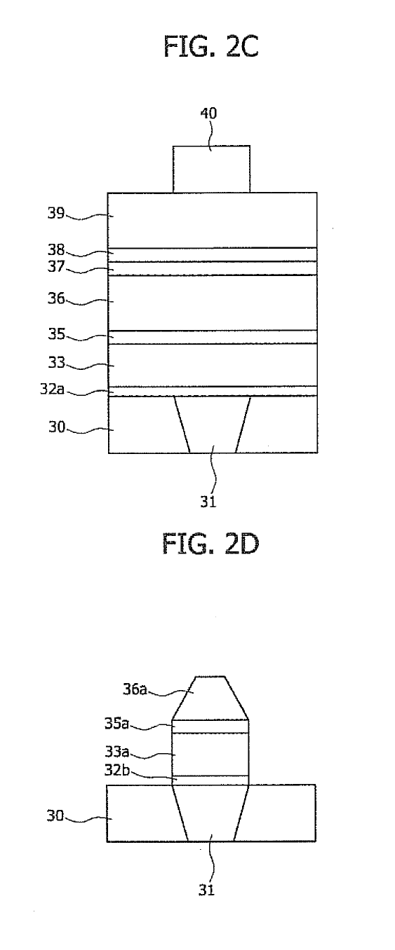

FIGS. 2A to 2D are cross-sectional views illustrating a method for fabricating a semiconductor device in accordance with a first embodiment of the present invention.

Referring to FIG. 2A, a bottom-electrode metal layer 32 is formed over a bottom layer 30 having a contact plug 31 formed therein. The bottom-electrode metal layer 32 may be formed of titanium nitride.

The bottom-electrode metal layer 32 is planarized by a CMP process, and it has a certain thickness, for example, 200 Å.

Referring to FIG. 213, the thickness of the bottom-electrode metal layer 32 is reduced to a set range, for example, about 50 Å by a wet etching process using a wet etching solution.

Since the CMP process has a limit in reducing a thickness of a layer to be planarized, it is difficult to form the bottom-electrode metal layer 32 to have a thickness of about 50 Å. As described above, however, the bottom-electrode metal layer 32 is desired to have a thickness of about 50 Å, in order to reliably perform an MTJ patterning process using top electrodes serving as a hard mask and a bottom electrode patterning process, which will be subsequently performed.

Therefore, in the method for fabricating a semiconductor device in accordance with the embodiment of the present invention, the CMP process is used to form the bottom-electrode metal layer 32 with a thickness of about 200 Å, and the wet etching process is used to form the bottom-electrode metal layer 32 with a thickness of about 50 Å. In this way, the reliability of the MTJ patterning process using top electrodes and the bottom electrode patterning process may be increased.

When the thickness of the bottom-electrode metal layer 32 is reduced excessively by the CMP process, the planarity between an insulation layer and a contact plug coupled to a bottom electrode may be degraded, and it is difficult to stably form a metal layer over the bottom-electrode metal layer 32. In this embodiment of the present invention, however, when the bottom-electrode metal layer 32 is formed to have a desired thickness by the CMP process and the wet etching process, the bottom-electrode metal layer 32 may be formed with high planarity. Therefore, the layer disposed over the bottom-electrode metal layer 32 may be stably formed.

Referring to FIG. 2C, a plurality of layers 33 for constructing an MTJ element is formed over the bottom-electrode metal layer 32a. The plurality of layers 33 for constructing the MTJ element may include a ferromagnetic layer, a tunnel insulation layer, and a ferromagnetic layer.

The layers 33 for constructing the MTJ element may include a fixed layer, a tunnel insulation layer, and a free layer and may be implemented by stacking various types of layers. The fixed layer refers to a layer of which the magnetization direction is fixed, and the free layer refers to a layer of which the magnetization direction is changed depending on data to be stored. The fixed layer may include a pinning layer and a pinned layer.

The pinning layer serves to fix the magnetization direction of the pinned layer and may be formed of an anti-ferromagnetic material. For example, the anti-ferromagnetic material may include IrMn, PtMn, MnO, MnS, MnTe, MnF₂, FeF₂, FeCl₂, FeO, CoCl₂, CoO, NiCl₂, or NiO. The pinning layer may include a single layer formed of any one of the above-described anti-ferromagnetic materials or a stacked layer of materials selected therefrom.

The pinned layer, of which the magnetization direction is fixed by the pinning layer, and the free layer may be formed of a ferromagnetic material. For example, the ferromagnetic material may include Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂. At this time, the pinned layer and the free layer may include a single layer formed of any one of the above-described ferromagnetic materials or a stacked layer of materials selected therefrom.

Furthermore, the pinned layer and the free layer may include a stacked layer of any one of the above-described ferromagnetic materials and a ruthenium layer (for example, CdFe/Ru/CoFe). Furthermore, the pinned layer and the free layer may include a synthetic anti-ferromagnetic (SAF) layer in which a ferromagnetic layer, an anti-ferromagnetic coupling spacer layer, and a ferromagnetic layer are sequentially stacked. The tunnel insulation layer serves as a tunneling barrier between the pinned layer and the free layer, and all kinds of materials having an insulation property may be used. For example, the tunnel insulation layer may be formed of MgO.

Continuously, first to third top-electrode metal layers 35 to 37 are formed over the plurality of layers 33 for constructing the MTJ element. The first to third top-electrode metal layers 35 to 37 may include a ruthenium layer, a tungsten layer, and a tantalum layer, respectively.

An insulation layer 38 is formed over the first to third top-electrode metal layers 35 to 37, and a carbon layer 39 is formed over the insulation layer 38. A photoresist pattern 40 is formed over the carbon layer 39.

Referring to FIG. 2D, the carbon layer 39 is patterned by using the photoresist pattern 40 as an etch mask. Using the patterned carbon layer 39 as an etch mask, the first to third top-electrode metal layers 35 to 37 are patterned to form top electrodes 35a to 36a. During this process, the insulation layer 38 and the third top-electrode metal layer 37 may be removed.

The plurality of layers 33 for constructing an MTJ element and the bottom-electrode metal layer 32a are patterned by using the top electrodes 35a and 36a, thereby forming an MTJ element 33a and a bottom electrode 32b. Then, a capping layer (not illustrated) is formed to cover the bottom electrode 32b, the MTJ element 33a, and the top electrode 35a and 36a. The capping layer may be formed of silicon nitride. The capping layer serves to prevent the MTJ element 34a from being damaged during a subsequent process for forming a contact plug which is coupled to the top electrodes 35a and 36a through an insulation layer (not illustrated) to be formed over the top electrodes 35a and 36a.

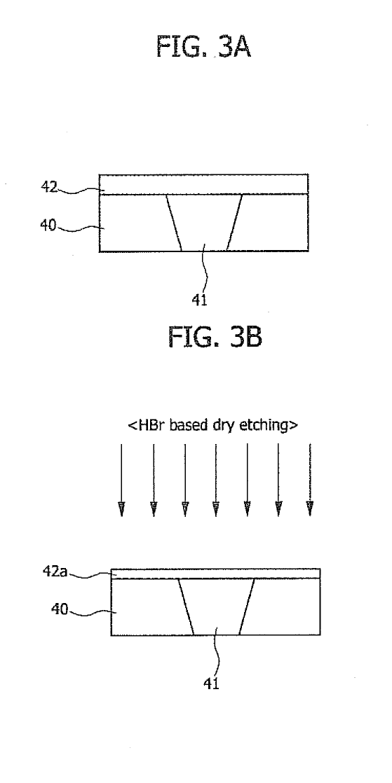

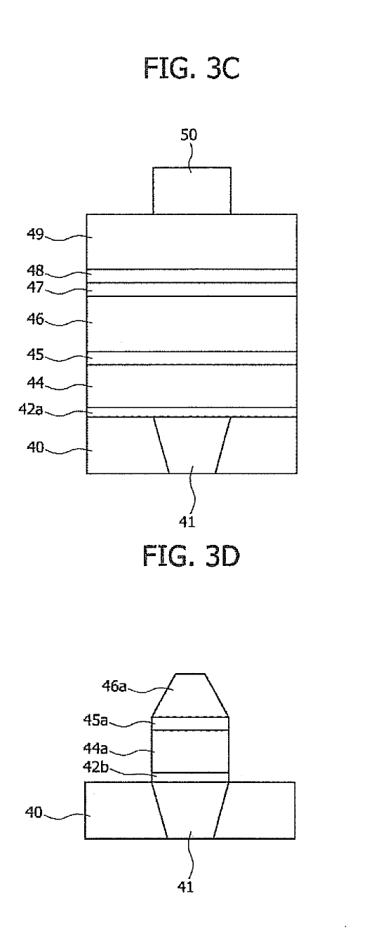

FIGS. 3A to 3D are cross-sectional views illustrating a method for fabricating a semiconductor device in accordance with a second embodiment of the present invention.

Referring to FIG. 3A, a bottom-electrode metal layer 42 is formed over a bottom layer 40 having a contact plug 41. The bottom-electrode metal layer 42 may be formed of titanium nitride.

The bottom-electrode metal layer 42 is planarized by a CMP process, and it has a certain thickness, for example, about 200 Å.

Referring to 3B, the thickness of the bottom-electrode metal layer 42 is reduced to a set range, for example, about 50 Å by a dry etching process using HBr as a base for etching gas.

Since the CMP process has a limit in reducing a thickness of a layer to be planarized, it is difficult to form the bottom-electrode metal layer 42 to have a thickness of about 50 Å. As described above, however, the bottom-electrode metal layer 42 is desired to have a thickness of about 50 Å, in order to reliably perform an MTJ patterning process using top electrodes serving as a hard mask and a bottom electrode patterning process, which will be subsequently performed.

Therefore, in the method for fabricating a semiconductor device in accordance with the embodiment of the present invention, the bottom-electrode metal layer 42 is formed to have a thickness of about 200 Å by the CMP process, and then it has a thickness of about 50 Å by the dry etching process. In this way, the reliability of the MTJ patterning process using top electrodes and the bottom electrode patterning process may be increased.

When the thickness of the bottom-electrode metal layer 42 is reduced excessively by the CMP process, the planarity between an insulation layer and a contact plug coupled to a bottom electrode may be degraded, and it is difficult to stably form a metal layer over the bottom-electrode metal layer 42. In this embodiment of the present invention, however, when the bottom-electrode metal layer 42 is formed to have a desired thickness by the CMP process and the wet etching process, the bottom-electrode metal layer 42 may be formed with high planarity. Therefore, the layer disposed over the bottom-electrode metal layer 42 may be stably formed.

Referring to FIG. 3C, a plurality of layers 44 for constructing an MTJ element are formed over the bottom-electrode metal layer 42a. The plurality of layers 44 for constructing an MTJ element may include a ferromagnetic layer, a tunnel insulation layer, and a ferromagnetic layer.

The plurality of layers 44 for constructing an MTJ element may include a fixed layer, a tunnel insulation layer, and a free layer and may be implemented by stacking various types of layers. The fixed layer refers to a layer of which the magnetization direction is fixed, and the free layer refers to a layer of which the magnetization direction is changed depending on data to be stored. The fixed layer may include a pinning layer and a pinned layer.

The pinning layer serves to fix the magnetization direction of the pinned layer and may be formed of an anti-ferromagnetic material. For example, the anti-ferromagnetic material may include IrMn, PtMn, MnO, MnS, MnTe, MnF₂, FeF₂, FeCl₂, FeO, CoCl₂, CoO, NiCl₂, or NiO. The pinning layer may include a single layer formed of any one of the above-described anti-ferromagnetic materials or a stacked layer of materials selected therefrom.

The pinned layer, of which the magnetization direction is fixed by the pinning layer, and the free layer may be formed of a ferromagnetic material. For example, the ferromagnetic material may include Fe, Co, Ni, Gd, Dy, NiFe, CoFe, MnAs, MnBi, MnSb, CrO₂, MnOFe₂O₃, FeOFe₂O₃, NiOFe₂O₃, CuOFe₂O₃, MgOFe₂O₃, EuO, or Y₃Fe₅O₁₂. At this time, the pinned layer and the free layer may include a single layer formed of any one of the above-described ferromagnetic materials or a stacked layer of materials selected therefrom.

Furthermore, the pinned layer and the free layer may include a stacked layer of any one of the above-described ferromagnetic materials and a ruthenium layer (for example, CdFe/Ru/CoFe). Furthermore, the pinned layer and the free layer may include an SAF layer in which a ferromagnetic layer, an anti-ferromagnetic coupling spacer layer, and a ferromagnetic layer are sequentially stacked. The tunnel insulation layer serves as a tunneling barrier between the pinned layer and the free layer, and all kinds of materials having an insulation property may be used. For example, the tunnel insulation layer may be formed of MgO.

Continuously, first to third top-electrode metal layers 45 to 47 are formed over the plurality of layers 44 for constructing an MTJ element. The first to third top-electrode metal layers 45 to 47 may be formed of a ruthenium layer, a tungsten layer, and a tantalum layer, respectively.

An insulation layer 48 is formed over the first to third top-electrode metal layers 45 to 47, and a carbon layer 49 is formed over the insulation layer 48. A photoresist pattern 50 is formed over the carbon layer 49.

Referring to FIG. 3D, the carbon layer 49 is patterned by using the photoresist pattern 50 as an etch mask. Using the patterned carbon layer 49 as an etch mask, the first to third top-electrode metal layers 45 to 47 are patterned to form top electrodes 45a to 46a. During this process, the insulation layer 48 and the third top-electrode metal layer 47 may be removed.

The plurality of layers 44 for constructing an MTJ element and the bottom-electrode metal layer 42a are patterned by using the top electrodes 45a and 46a, thereby forming an MTJ element 44a and a bottom electrode 42b. Then, a capping layer (not illustrated) is formed to cover the bottom electrode 42b, the MTJ element 44a, and the top electrode 45a and 46a. The capping layer may be formed of silicon nitride. The capping layer serves to prevent the MTJ element 44a from being damaged during a subsequent process for forming a contact plug which is coupled to the top electrodes 45a and 46a through an insulation layer (not illustrated) to be formed over the top electrodes 45a and 46a.

In the embodiments of the present invention, the method for fabricating a semiconductor device having an MTJ element has been described. However, the method for fabricating a semiconductor device in accordance with the embodiments of the present invention may be applied to a semiconductor device using other magnetoresistive elements, such as ReRAM.

In accordance with the embodiments of the present invention, the reliability of the fabrication process of the MTJ element may be increased. In particular, the reliability of the patterning process of the MTJ element is increased.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a semiconductor device, comprising:
forming a bottom-electrode metal layer over a substrate;
planarizing the bottom-electrode metal layer by a first thickness through a chemical mechanical polishing (CMP) process;
etching the bottom-electrode metal layer by a second thickness through a wet etching process;
forming a plurality of layers of a magnetic tunneling junction (MTJ) element over the bottom-electrode metal layer;
forming a top electrode over the plurality of layers; and
forming the MTJ element and a bottom electrode by etching the plurality of layers and the bottom-electrode metal layer using the top electrode as an etch mask.

2. The method of claim 1, wherein the forming of the top electrode comprises:
forming a top-electrode metal layer over the plurality of layers;
forming a carbon layer pattern over the top-electrode metal layer; and
forming the top electrode by patterning the top-electrode metal layer using the carbon layer pattern as an etch mask.

3. The method of claim 2, wherein the forming of the carbon layer pattern comprises:
forming a carbon layer over the top-electrode metal layer;
forming a photoresist pattern over the carbon layer; and
forming the carbon layer pattern by patterning the carbon layer using the photoresist pattern as an etch mask.

4. The method of claim 1, wherein the bottom electrode has a thickness of 50 Å or less.

5. The method of claim 1, wherein the bottom electrode comprises titanium nitride.

6. The method of claim 1, wherein the first thickness is equal to or less than 200 Å, and the second thickness is equal to or less than 50 Å.

7. A method for fabricating a semiconductor device, comprising:
forming a bottom-electrode metal layer over a substrate;
planarizing the bottom-electrode metal layer by a first thickness through a chemical mechanical polishing (CMP) process;
etching the bottom-electrode metal layer by a second thickness through a dry etching process;
forming a plurality of layers of a magnetic tunneling junction (MTJ) element over the bottom-electrode metal layer;
forming a top electrode over the plurality of layers; and
forming the MTJ element and a bottom electrode by etching the plurality of layers and the bottom-electrode metal layer using the top electrode an etch mask.

8. The method of claim 7, wherein the forming of the top electrode comprises:
forming a top-electrode metal layer over the plurality of layers;
forming a carbon layer pattern over the top-electrode metal layer; and
forming the top electrode by patterning the top-electrode metal layer using the carbon layer pattern as an etch mask.

9. The method of claim 8, wherein the forming of the carbon layer pattern comprises:
forming a carbon layer over the top-electrode metal layer;
forming a photoresist pattern over the carbon layer; and
forming the carbon layer pattern by patterning the carbon layer using the photoresist pattern as an etch mask.

10. The method of claim 7, wherein the bottom electrode has a thickness of 50 Å or less.

11. The method of claim 7, wherein the bottom electrode comprises titanium nitride.

12. The method of claim 7, wherein the first thickness is equal to or less than 200 Å, and the second thickness is equal to or less than 50 Å.

13. The method of claim 7, wherein the dry etching process uses on HBr as a base of etching gas.

14. A method for fabricating a semiconductor device, comprising:
forming a metal layer of a bottom electrode over a substrate;
performing a first etching process to form the metal layer of a first thickness;
performing a second etching process to form the metal layer of a second thickness;
forming a plurality of layers of a magnetic tunneling junction (MTJ) element over the metal layer;
forming a top electrode over the plurality of layers; and
forming the MTJ element and a bottom electrode by etching the plurality of layers and the metal layer using the top electrode as an etch mask.

15. The method of claim 14, wherein the first etching process comprises a chemical mechanical polishing (CMP) process to planarize the metal layer.

16. The method of claim 14, wherein the second etching process comprises a wet etching process or a dry etching process.
